(19) United States
(12) Patent Application Publication
(10) Pub. No.: US 2026/0303022 A1
(43) Pub. Date: Oct. 1, 2026

(54) CASCODE AMPLIFIER CIRCUIT

(71) Applicant: Murata Manufacturing Co., Ltd., Nagaokakyo-shi (JP)

(72) Inventor: Shota ISHIHARA, Nagaokakyo-shi (JP)

(21) Appl. No.: 19/568,941

(22) Filed: Mar. 17, 2026

(30) Foreign Application Priority Data
Mar. 27, 2025 (JP) 2025-053019

(51) Int. Cl. H03F 1/02; H03F 3/21

(52) U.S. Cl. CPC H03F 1/0205; H03F 3/21; H03F 2200/21; H03F 2200/451; H03F 2200/468

(57) ABSTRACT

A radio frequency signal is inputted to a first transistor. At least one second transistor is cascode-connected to the first transistor. A bias circuit supplies bias to the at least one second transistor. A power supply voltage that is variable is applied, through a power supply wiring line, to a cascode connection circuit including the first transistor and the at least one second transistor. The bias circuit includes a resistor voltage divider circuit, a bias voltage source, and at least one first diode. The resistor voltage divider circuit is connected between the power supply wiring line and a reference potential, has at least one voltage dividing point corresponding to the at least one second transistor, and supplies bias to the corresponding second transistor based on a voltage at the at least one voltage dividing point.

### CROSS REFERENCE TO RELATED APPLICATION

This application claims priority from Japanese Patent Application No. 2025-053019, filed on Mar. 27, 2025. The content of this application is incorporated herein by reference in its entirety.

### BACKGROUND OF THE DISCLOSURE

### 1. Field of the Disclosure

The present disclosure relates to a cascode amplifier circuit.

### 2. Description of the Related Art

Cascode amplifier circuits that modulate a power supply voltage based on an input signal by using the envelope tracking method are publicly known (Japanese Unexamined Patent Application Publication (Translation of PCT Application) No. 2016-530845). In the cascode amplifier circuit disclosed in Japanese Unexamined Patent Application Publication (Translation of PCT Application) No. 2016-530845, a power supply voltage modulated based on an input signal is divided in a resistor voltage divider circuit to generate a bias voltage. The bias voltage is supplied to a cascode transistor.

### BRIEF SUMMARY OF THE DISCLOSURE

In a state where a power supply voltage is decreased, a bias voltage generated based on the decreased power supply voltage is also decreased. An excessively decreased bias voltage to the cascode transistor causes the cascode transistor to enter an off state, which causes the gain of the cascode amplifier circuit to be decreased on occasions. Accordingly, it is a possible benefit of the present disclosure to provide a cascode amplifier circuit in which a gain is prevented from decreasing even in a state where a power supply voltage is decreased.

According to an aspect of the present disclosure, there is provided a cascode amplifier circuit including: a first transistor to which a radio frequency signal is input; at least one second transistor that is cascode-connected to the first transistor; a bias circuit that supplies bias to the at least one second transistor; and a power supply wiring line through which a power supply voltage that is variable is applied to a cascode connection circuit including the first transistor and the at least one second transistor. The bias circuit includes a resistor voltage divider circuit that is connected between the power supply wiring line and a reference potential, that has at least one voltage dividing point corresponding to the at least one second transistor, and that supplies bias to the corresponding second transistor based on a voltage at the at least one voltage dividing point, a bias voltage source that generates a reference voltage that serves as a base for the bias supplied to the at least one second transistor, and at least one first diode connected between an output node of the bias voltage source and the at least one voltage dividing point, the at least one first diode being connected in a direction serving as a forward direction from the output node of the bias voltage source to the at least one voltage dividing point.

Even if the power supply voltage applied to the power supply wiring line is decreased, the reference voltage is applied from the bias voltage source to the voltage dividing point of the resistor voltage divider circuit via the first diode. Accordingly, even if the power supply voltage is decreased, the voltage at the voltage dividing point is prevented from being excessively decreased. The bias is supplied to the second transistor based on the voltage at the voltage dividing point, and thus the gain of the cascode amplifier circuit may be prevented from being decreased.

### BRIEF DESCRIPTION OF THE SEVERAL VIEWS OF THE DRAWINGS

FIG. 1 is an equivalent circuit diagram of a cascode amplifier circuit according to First Embodiment;

FIG. 2 is a graph illustrating an example of relationships between a power supply voltage Vdd₁ and bias voltages Vg₂, Vg₃, Vg₄, and Vg₅ to respective second transistors 12;

FIG. 3 is an equivalent circuit diagram of a cascode amplifier circuit according to a comparative example;

FIG. 4 is a graph illustrating relationships between the power supply voltage Vdd₁ to the cascode amplifier circuit according to the comparative example illustrated in FIG. 3 and the bias voltages;

FIG. 5 is an equivalent circuit diagram of a cascode amplifier circuit according to another comparative example;

FIG. 6 is a graph illustrating relationships between the power supply voltage Vdd₁ to the cascode amplifier circuit according to the comparative example illustrated in FIG. 5 and the bias voltages;

FIG. 7 is an equivalent circuit diagram of a cascode amplifier circuit according to Second Embodiment;

FIG. 8 is an equivalent circuit diagram of a cascode amplifier circuit according to Third Embodiment;

FIG. 9 is a graph illustrating an example of relationships between the power supply voltage Vdd₁ and the bias voltages Vg₂, Vg₃, Vg₄, and Vg₅ of the respective second transistors 12;

FIG. 10 is an equivalent circuit diagram of a cascode amplifier circuit according to Fourth Embodiment;

FIG. 11 is an equivalent circuit diagram of a cascode amplifier circuit according to Fifth Embodiment;

FIG. 12 is an equivalent circuit diagram of a cascode amplifier circuit according to Sixth Embodiment;

FIG. 13 is an equivalent circuit diagram of a bias voltage source 22 of a cascode amplifier circuit according to Seventh Embodiment; and

FIG. 14 is an equivalent circuit diagram of a bias voltage source 22 of a cascode amplifier circuit according to Eighth Embodiment.

### DETAILED DESCRIPTION OF THE DISCLOSURE

### First Embodiment

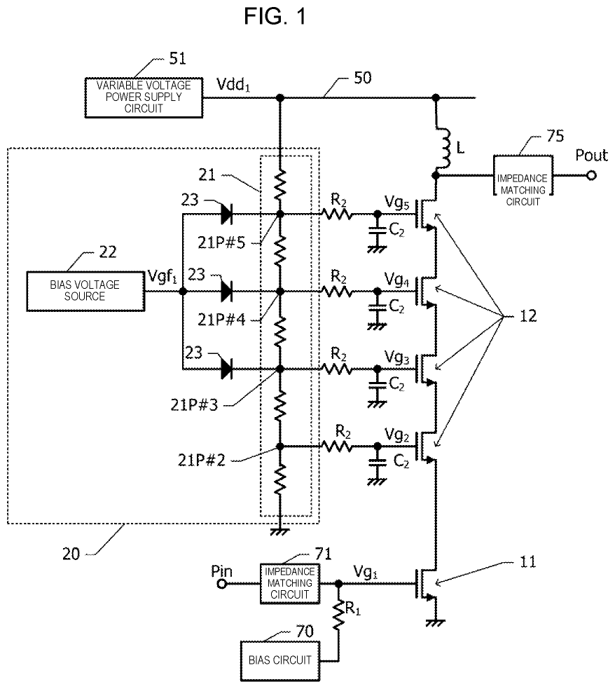

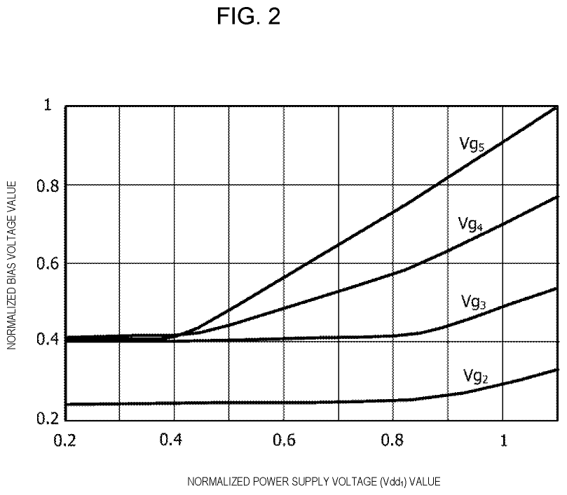

A cascode amplifier circuit according to First Embodiment will be described with reference to FIGS. 1 and 2.

FIG. 1 is an equivalent circuit diagram of the cascode amplifier circuit according to First Embodiment. A radio frequency signal Pin is inputted to the gate of a first transistor 11 via an impedance matching circuit 71. A bias voltage Vg₁ is supplied from a bias circuit 70 to the gate of the first transistor 11 via a resistive element R₁.

Four second transistors 12 connected in series are cascode-connected to the first transistor 11. The number of the second transistors 12 is not limited to 4 and may be at least 1. For example, the number of second transistors 12 may be 1, 2, 3, 5, or more.

NMOSFETs are used for the first transistor 11 and the second transistors 12. The source of the first transistor 11 is connected (grounded) to the reference potential, and a series circuit including the plurality of second transistors 12 is connected to the drain of the first transistor 11. The first transistor 11 and the four second transistors 12 are distinguished from each other in such a manner as to be numbered sequentially from the reference potential side in order. The first transistor 11 is a transistor at the first stage, and the four second transistors 12 are assigned sequential numbers from 2 to 5. The second transistor 12 assigned n as the sequential number is referred to as the second transistor 12 at the nth stage. The gates of the plurality of second transistors 12 are AC-grounded via respective capacitors C₂.

A bias circuit 20 supplies bias voltages to the respective gates of the plurality of second transistors 12 via respective resistive elements R₂. The bias voltages supplied to the gates of the second transistors 12 from the second stage to the fifth stage are denoted by Vg₂, Vg₃, Vg₄, and Vg₅.

A power supply wiring line 50 is connected to a variable voltage power supply circuit 51. The variable voltage power supply circuit 51 applies, to the power supply wiring line 50, a power supply voltage Vdd₁ that is variable and that is modulated based on the radio frequency signal Pin by using a technology such as the envelope tracking method (ET method) or the average power tracking method (APT method). The power supply voltage Vdd₁ is variable within a set operating range.

The power supply wiring line 50 is used to apply the power supply voltage Vdd₁ to the cascode connection circuit composed of the first transistor 11 and the four second transistors 12 via a choke coil L. In other words, the drain of the second transistor 12 at the fifth stage is connected to the power supply wiring line 50 via the choke coil L. A radio frequency signal Pout that is amplified is outputted from a point of connection between the choke coil L and the cascode connection circuit composed of the first transistor 11 and the four second transistors 12 via an impedance matching circuit 75.

The configuration of the bias circuit 20 will then be described. A resistor voltage divider circuit 21 is connected between the power supply wiring line 50 and the reference potential. The resistor voltage divider circuit 21 has voltage dividing points 21P corresponding to the plurality of second transistors 12. If the number of second transistors 12 is 1, the number of voltage dividing points 21P of the resistor voltage divider circuit 21 is also 1. The resistor voltage divider circuit 21 supplies respective biases to the second transistors 12 based on the respective voltages at the plurality of voltage dividing points 21P.

For example, the respective voltages at the plurality of voltage dividing points 21P are applied to the gates of the corresponding second transistors 12 via the resistive elements R₂. The plurality of voltage dividing points 21P of the resistor voltage divider circuit 21 are assigned Identification Nos. #2, #3, #4, and #5 in order from the reference potential side, and the voltage dividing points 21P with the identification Nos. #2, #3, #4, and #5 are respectively connected to the gates of the second transistors 12 at the second stage, the third stage, the fourth stage, and the fifth stage. That is, a subset of the voltage dividing points 21P that is closer to the reference potential is connected to one or more gates of a remaining subset of the plurality of second transistors 12 that is closer to the first transistor 11.

The bias voltage source 22 generates a reference voltage Vgf1. For example, a voltage regulator is used as the bias voltage source 22. The reference voltage Vgf₁ serves as a base of the bias voltages to be supplied to the plurality of second transistors 12. First diodes 23 are connected between the output node of the bias voltage source 22 and at least a subset of the plurality of voltage dividing points 21P of the resistor voltage divider circuit 21. Each first diode 23 is connected in a direction serving as a forward direction from the output node of the bias voltage source 22 to the voltage dividing points 21P. In First Embodiment, the first diode 23 is not connected to the voltage dividing point 21P with Identification No. #2, and the first diodes 23 are connected to the voltage dividing points 21P with Identification Nos. #3, #4, and #5.

Relationships between the power supply voltage Vdd₁ and the bias voltages Vg₂, Vg₃, Vg₄, and Vg₅ to the second transistors 12 will then be described with reference to FIG. 2. FIG. 2 is a graph illustrating an example of the relationships between the power supply voltage Vdd₁ and the bias voltages Vg₂, Vg₃, Vg₄, and Vg₅ to the second transistors 12. The bias voltages Vg₂, Vg₃, Vg₄, and Vg₅ are respectively equal to voltages at the corresponding voltage dividing points 21P with Identification Nos. #2, #3, #4, and #5 of the resistor voltage divider circuit 21. The horizontal axis of the graph illustrated in FIG. 2 represents the normalized value of the power supply voltage Vdd₁, and the vertical axis represents the normalized value of the bias voltages. The power supply voltage Vdd₁ and the bias voltages are normalized by using the same reference voltage.

The reference voltage Vgf₁ is lower than the upper-limit value of the operating range of the power supply voltage Vdd₁ and higher than the lower-limit value. For example, the normalized value of the upper-limit value of the operating range of the power supply voltage Vdd₁ is 1, and the lower-limit value is 0.2. The normalized value of the reference voltage Vgf₁ is, for example, 0.4. Among the plurality of voltage dividing points 21P of the resistor voltage divider circuit 21, the voltages at the voltage dividing points 21P with Identification Nos. #3, #4, and #5 connected to the bias voltage source 22 via the first diodes 23 do not become lower than or equal to a voltage that is the reference voltage Vgf₁-Vf. Note that Vf denotes a forward voltage of the first diode 23.

When the normalized value of the power supply voltage Vdd₁ is 1 that is the upper-limit value of the operating range, the values of the bias voltages Vg₅, Vg₄, Vg₃, and Vg₂ become almost equal to values obtained by the voltage division by the resistor voltage divider circuit 21. The voltage division ratio of the resistor voltage divider circuit 21 is set such that the bias voltages Vg₅, Vg₄, and Vg₃ are higher than the reference voltage Vgf₁ and such that the bias voltage Vg₂ is lower than the reference voltage Vgf1.

If the power supply voltage Vdd₁ decreases, the bias voltages Vg₅, Vg₄, Vg₃, and Vg₂ also decrease. If the bias voltages Vg₅, Vg₄, and Vg₃ each decrease to the voltage of the reference voltage Vgf₁-Vf, and if the power supply voltage Vdd₁ thereafter decreases to the voltage or lower, the first diodes 23 become conductive. The bias voltages Vg₅, Vg₄, and Vg₃ thus stop decreasing and have substantially constant values. The bias voltage Vg₂ has a value obtained by dividing a potential difference between the bias voltage Vg₃ and the reference potential by the resistor voltage divider circuit 21. Accordingly, if the power supply voltage Vdd₁ decreases, the bias voltage Vg₂ also stops decreasing at the time when the bias voltage Vg₃ stops decreasing.

The effects of First Embodiment will then be described.

Excessive decreases in the bias voltages to the second transistors 12 cause the second transistors 12 to turn off, and thus the gain of the cascode amplifier circuit is considerably decreased. In First Embodiment, as illustrated in FIG. 2, the bias voltage source 22 and the plurality of first diodes 23 limit the lower-limit value of the bias voltages to the second transistors 12. As a result, the considerable decrease in the gain of the cascode amplifier circuit is prevented.

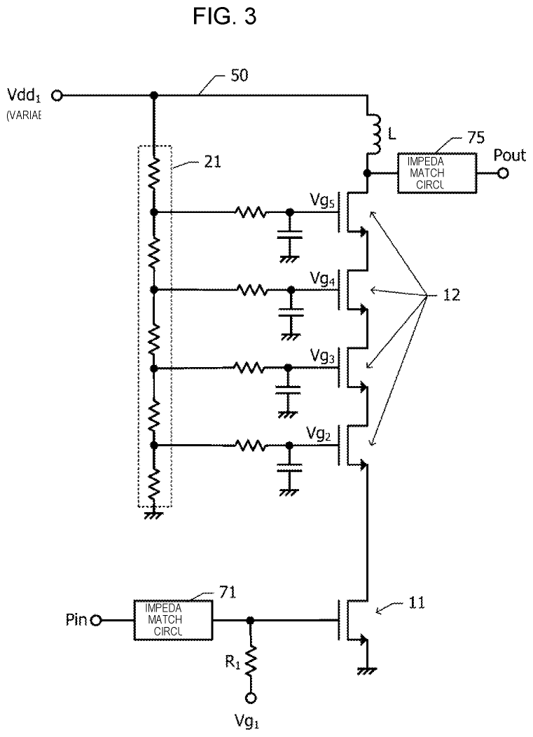

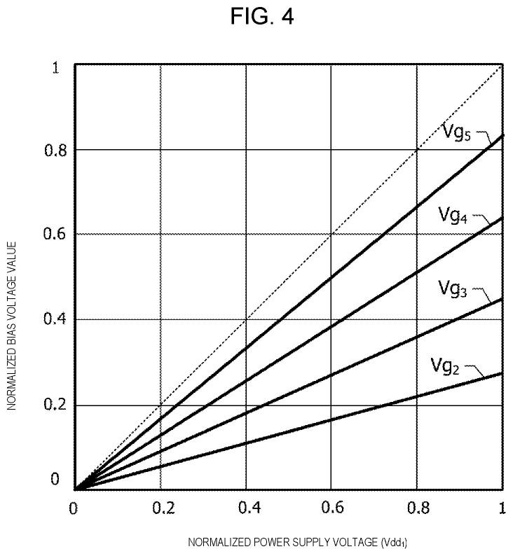

Effects of First Embodiment will then be described as compared with a comparative example illustrated in FIGS. 3 and 4. FIG. 3 is an equivalent circuit diagram of a cascode amplifier circuit according to the comparative example. In the comparative example illustrated in FIG. 3, the bias voltage source 22 and the first diodes 23 in First Embodiment (FIG. 1) are not connected to the resistor voltage divider circuit 21.

FIG. 4 is a graph illustrating relationships between the power supply voltage Vdd₁ and the bias voltages in the cascode amplifier circuit according to the comparative example illustrated in FIG. 3. The horizontal axis of the graph in FIG. 4 represents the normalized value of the power supply voltage Vdd₁, and the vertical axis represents the normalized value of the bias voltages. In this comparative example, the bias voltages Vg₅, Vg₄, Vg₃, and Vg₂ change in proportion to the power supply voltage Vdd₁. Accordingly, if the normalized value of the power supply voltage Vdd₁ decreases to the lower-limit value of 0.2 in the operating range, the normalized value of the bias voltages Vg₅, Vg₄, Vg₃, and Vg₂ decreases to a value lower than 0.2.

With this configuration, when the gain at the time when the power supply voltage Vdd₁ has the upper-limit value of the operating range (the normalized value is 1) is used as the reference, a gain close to the lower-limit value has a large deviation (decrease amount). Specifically, when the power supply voltage Vdd₁ is close to the lower-limit value of the operating range (for example, the normalized value is close to about 0.2), the bias voltages Vg₂, Vg₃, Vg₄, and Vg₅ are excessively low, and thus the gain is considerably decreased.

By contrast, in First Embodiment, as illustrated in FIG. 2, when the power supply voltage Vdd₁ is close to the lower-limit value of the operating range (for example, the normalized value is about 0.1), the bias voltages Vg₃, Vg₄, and Vg₅ are kept at values higher than the lower-limit value of the operating range of the power supply voltage Vdd₁, that is, a value obtained by subtracting the forward voltages Vf of the first diodes 23 from the reference voltage Vgf1. Accordingly, even in a state where the power supply voltage Vdd₁ is decreased close to the lower-limit value of the operating range, the gain decrease may be prevented. The source voltage of the second transistor 12 at the second stage is lower than the source voltages at the second transistors 12 at the third stage and higher stages, and thus the decrease in the bias voltage Vg₂ close to the lower-limit value of the power supply voltage Vdd₁ (the normalized value of 0.2) does not cause the second transistors 12 to turn off. Accordingly, the gain decrease in the cascode amplifier circuit is prevented. The voltage division ratio of the resistor voltage divider circuit 21 and the reference voltage Vgf₁ are set such that even if the power supply voltage Vdd₁ is decreased to the lower-limit value (the normalized value of 0.2), the bias voltage Vg₂ is kept at a value higher than the lower-limit value of the power supply voltage Vdd₁.

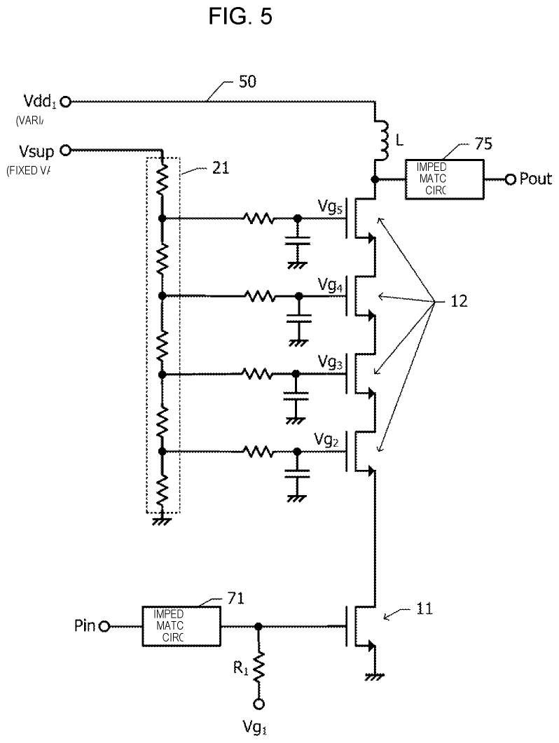

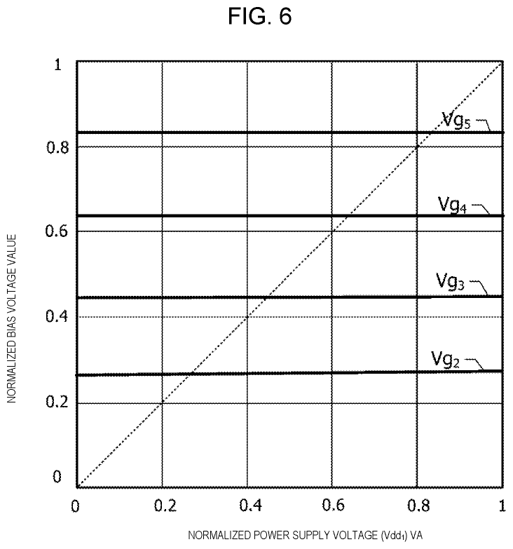

Effects of First Embodiment will then be described as compared with the comparative example illustrated in FIGS. 5 and 6. FIG. 5 is an equivalent circuit diagram of a cascode amplifier circuit according to another comparative example. In the comparative example illustrated in FIG. 5, the resistor voltage divider circuit 21 is connected between a fixed voltage Vsup and the reference potential.

FIG. 6 is a graph illustrating relationships between the power supply voltage Vdd₁ and the bias voltages in the cascode amplifier circuit according to the comparative example illustrated in FIG. 5. The horizontal axis of the graph in FIG. 6 represents the normalized value of the power supply voltage Vdd₁, and the vertical axis represents the normalized value of the bias voltages. Since the fixed voltage Vsup is applied to the resistor voltage divider circuit 21, the bias voltages Vg₂, Vg₃, Vg₄, and Vg₅ are constant even if the power supply voltage Vdd₁ is changed. As a result, the gain decrease at the time when the power supply voltage Vdd₁ is decreased close to the lower-limit value is prevented. However, there arises an issue described below.

In the state where the power supply voltage Vdd₁ is decreased close to the lower-limit value of the operating range (for example, the normalized value is about 0.2), the bias voltages Vg₃, Vg₄, and Vg₅ are considerably higher than the power supply voltage Vdd₁. Accordingly, in particular in the second transistor 12 at the fifth stage, there is a large difference between the bias voltage Vg₅ and the power supply voltage Vdd₁, and the gate-drain voltage of the second transistor 12 at the fifth stage exceeds a withstand voltage. The reliability of the cascode amplifier circuit is thus deteriorated.

By contrast, in First Embodiment, as illustrated in FIG. 2, in the state where the power supply voltage Vdd₁ decreases close to the lower-limit value of the operating range, the bias voltages Vg₃, Vg₄, and Vg₅ decrease to a value substantially the same as a value obtained by subtracting the forward voltages Vf of the first diodes 23 from the reference voltage Vgf₁. The respective gate-drain voltages of the second transistors 12 thus become less likely to exceed their withstand voltages. The reliability of the cascode amplifier circuit is prevented from being deteriorated.

Besides the comparative examples illustrated in FIGS. 3 and 5, it is also possible to change the bias voltages Vg₂, Vg₃, Vg₄, and Vg₅ by using the digital computation circuit, as illustrated in FIG. 2. However, this configuration requires A/D conversion by an A/D converter that detects the power supply voltage Vdd₁, digital computation, and D/A conversion by a D/A converter that generates a bias voltage. This leads to lower response speeds of the bias voltages Vg₂, Vg₃, Vg₄, and Vg₅ in response to a change in the power supply voltage Vdd₁.

It is also possible to use an analog computation circuit using an operational amplifier, instead of the digital computation circuit. However, also in this configuration, the response speeds of the bias voltages Vg₂, Vg₃, Vg₄, and Vg₅ in response to a change in the power supply voltage Vdd₁ are limited due to the operating speed of the operational amplifier.

By contrast, in First Embodiment, the bias voltages Vg₂, Vg₃, Vg₄, and Vg₅ are generated by the resistor voltage divider circuit 21, the bias voltage source 22, and the first diodes 23 that are connected to the power supply voltage Vdd₁ (FIG. 1), and thus almost no delay in a change in the bias voltages Vg₂, Vg₃, Vg₄, and Vg₅ in response to a change in the power supply voltage Vdd₁ occurs.

As described above, in First Embodiment, the gain deviation at a change in the power supply voltage Vdd₁ may be prevented, high reliability may be kept, and sufficiently high response speeds of the bias voltages Vg₂, Vg₃, Vg₄, and Vg₅ in response to a change in the power supply voltage Vdd₁ may be achieved.

NMOSFETs are used for the first transistor 11 and the second transistors 12 in the cascode amplifier circuit according to First Embodiment; however, bipolar transistors may be used. In the case where the bipolar transistors are used for the first transistor 11 and the second transistors 12, the source, the drain, and the gate of each of the first transistor 11 and the second transistors 12 may be read as an emitter, a collector, and a base in the description above.

### Second Embodiment

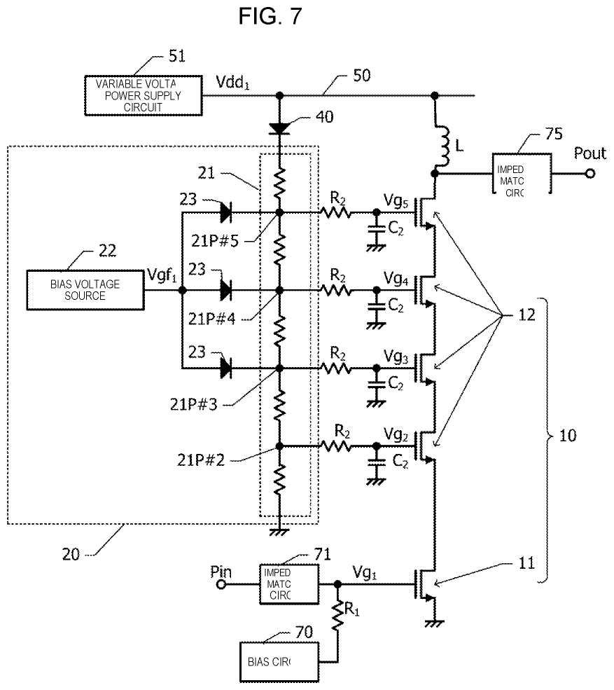

A cascode amplifier circuit according to Second Embodiment will then be described with reference to FIG. 7. The description of the configuration common to the cascode amplifier circuit according to First Embodiment described with reference to FIGS. 1 and 2 is hereinafter omitted.

FIG. 7 is an equivalent circuit diagram of the cascode amplifier circuit according to Second Embodiment. In First Embodiment (FIG. 1), the resistor voltage divider circuit 21 is directly connected to the power supply wiring line 50. By contrast, in Second Embodiment, a second diode 40 is connected between the power supply wiring line 50 and the resistor voltage divider circuit 21. The second diode 40 is connected in a direction serving as a forward direction from the power supply wiring line 50 to the resistor voltage divider circuit 21.

The effects of Second Embodiment will then be described.

The second diode 40 has a function of blocking current flowing from the bias voltage source 22 to the power supply wiring line 50 when the power supply voltage Vdd₁ decreases and becomes lower than the reference voltage Vgf₁. Unnecessary energy consumption due to the current flowing from the bias voltage source 22 to the power supply wiring line 50 may thereby be prevented.

### Third Embodiment

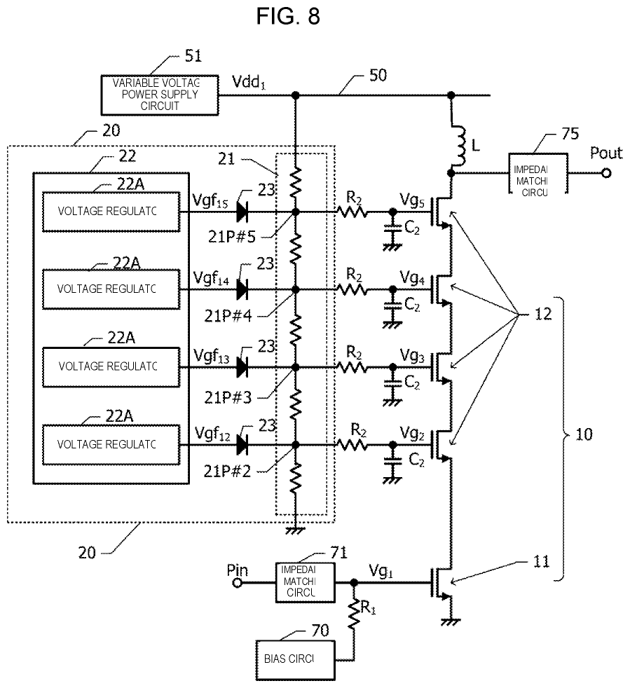

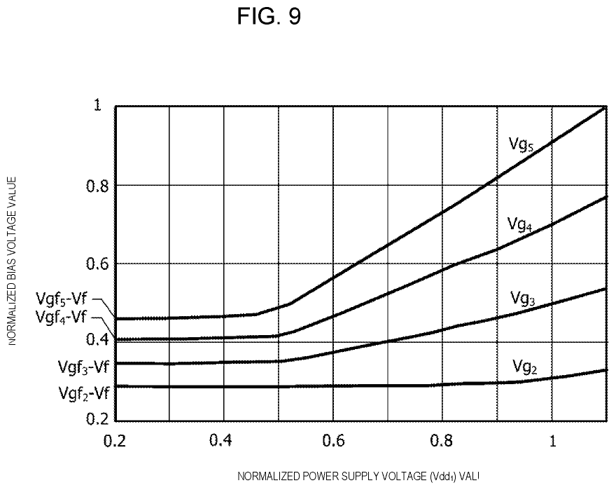

A cascode amplifier circuit according to Third Embodiment will then be described with reference to FIGS. 8 and 9. The description of the configuration common to the cascode amplifier circuit according to First Embodiment described with reference to FIGS. 1 and 2 is hereinafter omitted.

FIG. 8 is an equivalent circuit diagram of the cascode amplifier circuit according to Third Embodiment. In First Embodiment (FIG. 1), the reference voltage Vgf₁ is applied to the anodes of the plurality of first diodes 23. By contrast, in Third Embodiment, the bias voltage source 22 has a plurality of output nodes, and reference voltages having different levels are applied to the respective anodes of the plurality of first diodes 23.

In addition, in First Embodiment (FIG. 1), no first diode 23 is connected to the voltage dividing point 21P with Identification No. #2 corresponding to the second transistor 12 at the second stage. By contrast, in Third Embodiment, the first diodes 23 are connected to the plurality of voltage dividing points 21P with Identification Nos. #2, #3, #4, and #5 corresponding to all of the second transistors 12 from the second stage to the fifth stage. As with First Embodiment, in Third Embodiment, the configuration in which no first diode 23 is connected to the voltage dividing point 21P with Identification No. #2 corresponding to the second transistor 12 at the second stage may be used.

The bias voltage source 22 includes a plurality of voltage regulators 22A corresponding to the plurality of respective first diodes 23. The plurality of voltage regulators 22A respectively apply reference voltages Vgf₁₂, Vgf₁₃, Vgf₁₄, and Vgf₁₅ to the anodes of the first diodes 23 connected to the voltage dividing points 21P with Identification Nos. #2, #3, #4, and #5. The magnitude relationship of the reference voltages Vgf₁₂, Vgf₁₃, Vgf₁₄, and Vgf₁₅ is as follows.
Vgf₁₂<Vgf₁₃<Vgf₁₄<Vgf₁₅

Relationships between the power supply voltage Vdd₁ and the bias voltages Vg₂, Vg₃, Vg₄, and Vg₅ to the second transistors 12 will then be described with reference to FIG. 9. FIG. 9 is a graph illustrating an example of the relationships between the power supply voltage Vdd₁ and the bias voltages Vg₂, Vg₃, Vg₄, and Vg₅ to the second transistors 12. In First Embodiment (FIG. 2), a decrease in the power supply voltage Vdd₁ close to the lower-limit value of the operating range causes all of the bias voltages Vg₃, Vg₄, and Vg₅ to approach the value obtained by subtracting the forward voltages Vf of the first diodes 23 from the reference voltage Vgf₁. By contrast, in Third Embodiment, a decrease in the power supply voltage Vdd₁ close to the lower-limit value of the operating range causes the bias voltages Vg₂, Vg₃, Vg₄, and Vg₅ to approach respective values obtained by respectively subtracting the forward voltages Vf of the first diodes 23 from the different reference voltages Vgf₁₂, Vgf₁₃, Vgf₁₄, and Vgf₁₅.

The effects of Third Embodiment will then be described.

In Third Embodiment, the lower-limit values of the bias voltages Vg₂, Vg₃, Vg₄, and Vg₅ at the time when the power supply voltage Vdd₁ approaches the lower-limit value of the operating range may be set individually. As a result, respective bias voltages appropriate for the second transistors 12 from the second stage to the fifth stage may be supplied.

### Fourth Embodiment

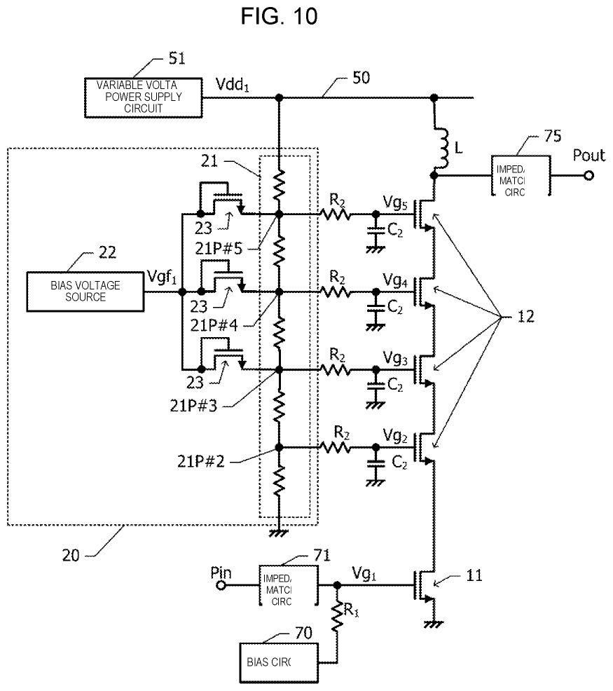

A cascode amplifier circuit according to Fourth Embodiment will then be described with reference to FIG. 10. The description of the configuration common to the cascode amplifier circuit according to First Embodiment described with reference to FIGS. 1 and 2 is hereinafter omitted.

FIG. 10 is an equivalent circuit diagram of the cascode amplifier circuit according to Fourth Embodiment. In First Embodiment (FIG. 1), p-n junction diodes are used for the first diodes 23. By contrast, in Fourth Embodiment, diode-connected NMOSFETs, that is, NMOSFETs each having a gate and a drain that are connected, are used as the first diodes 23. In each diode-connected NMOSFET, the drain and the source are respectively used as the anode and the cathode of the diode. Diode-connected PMOSFETs, that is, PMOSFETs each having a gate and a drain that are connected may be used as the first diodes 23. In using the PMOSFETs, the drain and the source are respectively used as the cathode and the anode of the diode.

The effects of Fourth Embodiment will then be described.

As with First Embodiment, in Fourth Embodiment, not only the considerable decrease in the gain of the cascode amplifier circuit but also reliability deterioration is prevented. Further, in Fourth Embodiment, the first diodes 23 may be formed simultaneously with the first transistor 11 and the second transistors 12 in a manufacturing process.

A cascode amplifier circuit according to a modification of Fourth Embodiment will then be described. In the modification of Fourth Embodiment, as with the cascode amplifier circuit according to Second Embodiment (FIG. 7), the second diode 40 may be connected between the power supply wiring line 50 and the resistor voltage divider circuit 21. In this case, a diode-connected NMOSFET or PMOSFET may be used for the second diode 40.

### Fifth Embodiment

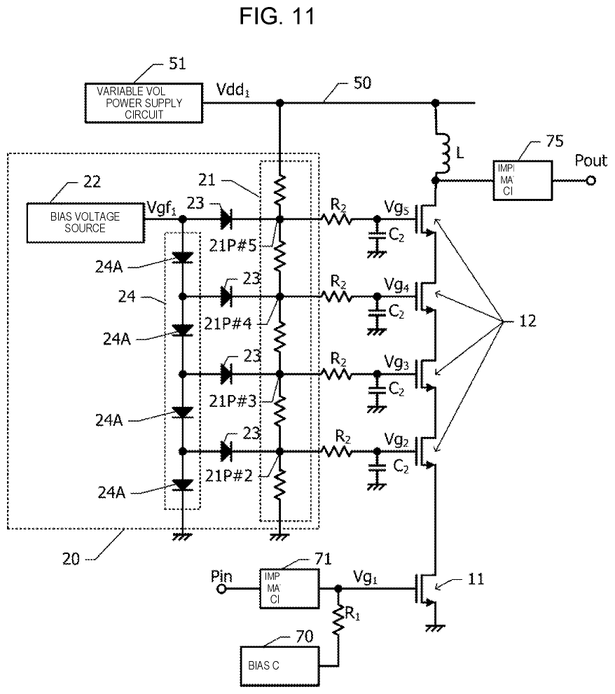

A cascode amplifier circuit according to Fifth Embodiment will then be described with reference to FIG. 11. The description of the configuration common to the cascode amplifier circuit according to First Embodiment described with reference to FIGS. 1 and 2 is hereinafter omitted.

FIG. 11 is an equivalent circuit diagram of the cascode amplifier circuit according to Fifth Embodiment. The cascode amplifier circuit according to Fifth Embodiment includes a multi-stage diode circuit 24 in addition to the components of the cascode amplifier circuit according to First Embodiment (FIG. 1), the multi-stage diode circuit 24 being connected between the output node of the bias voltage source 22 and the reference potential. The multi-stage diode circuit 24 includes a plurality of third diodes 24A connected at multiple stages. The plurality of third diodes 24A are connected in a direction serving as a forward direction from the reference voltage Vgf₁ at the output node of the bias voltage source 22 to the reference potential.

At least one of the plurality of first diodes 23 is connected to the bias voltage source 22 via at least one of the third diodes 24A of the multi-stage diode circuit 24. One or more of the first diodes 23 connected to one or more of the voltage dividing points 21P with one or more smaller identification number (one or more voltage dividing points 21P closer to the reference potential) are connected to the bias voltage source 22 via one or more of the third diodes 24A the number of which is greater than the number of remaining one or more third diodes 24A. The remaining one or more first diodes 23 are connected, via the remaining one or more third diodes 24A, to the one or more voltage dividing points 21P with one or more larger identification numbers (the remaining one or more voltage dividing points 21P closer to the power supply wiring line 50). In addition, at least one third diode 24A is connected between the anode of the first diode 23 connected to the voltage dividing point 21P with Identification No. #2 and the reference potential.

For example, the voltage dividing points 21P with Identification Nos. #2, #3, #4, and #5 are respectively connected to the gates of the second transistors 12 at the second stage, the third stage, the fourth stage, and the fifth stage. The anode of the first diode 23 connected to the voltage dividing point 21P with Identification No. #2 is connected to the bias voltage source 22 via three of the third diodes 24A. The anode of the first diode 23 connected to the voltage dividing point 21P with Identification No. #3 is connected to the bias voltage source 22 via two of the third diodes 24A. The anode of the first diode 23 connected to the voltage dividing point 21P with Identification No. #4 is connected to the bias voltage source 22 via one of the third diodes 24A. The anode of the first diode 23 connected to the voltage dividing point 21P with Identification No. #5 is connected to the bias voltage source 22 without no third diode 24A interposed therebetween.

The effects of Fifth Embodiment will then be described.

First, a case where the multi-stage diode circuit 24 is not connected and the voltages at the anodes of the plurality of first diodes 23 are all equal to the reference voltage Vgf₁ is reviewed. When the power supply voltage Vdd₁ becomes lower than the reference voltage Vgf₁, current flows on occasions to the power supply wiring line 50 via the voltage dividing point 21P with Identification No. #4 to the voltage dividing point 21P with Identification No. #5, depending on the voltage division ratio of the resistor voltage divider circuit 21. At this time, the bias voltage Vg₄ to the second transistor 12 at the fourth stage becomes higher than the bias voltage Vg₅ to the second transistor 12 at the fifth stage.

By contrast, in Fifth Embodiment, the voltages divided by the multi-stage diode circuit 24 are applied to the anodes of the plurality of first diodes 23. That is, the voltage applied to the anode of the first diode 23 connected to the voltage dividing point 21P with Identification No. #4 is lower than the voltage applied to the anode of the first diode 23 connected to the voltage dividing point 21P with Identification No. #5. As a result, even in the state where the power supply voltage Vdd₁ becomes lower than the reference voltage Vgf₁, the current is less likely to flow from the voltage dividing point 21P with Identification No. #4 to the voltage dividing point 21P with Identification No. #5. For this reason, the state where the bias voltage Vg₄ to the second transistor 12 at the fourth stage becomes higher than the bias voltage Vg₅ to the second transistor 12 at the fifth stage is less likely to occur.

As an example, the multi-stage diode circuit 24 is desirably designed such that voltage division of the reference voltage Vgf₁ by the multi-stage diode circuit 24 causes the reference voltages Vgf₁₂, Vgf₁₃, Vgf₁₄, and Vgf₁₅ illustrated in Third Embodiment (FIGS. 8 and 9) to be applied to the anodes of the respective first diodes 23 connected to the voltage dividing points 21P with Identification Nos. #2, #3, #4, and #5. In Fifth Embodiment, the one third diode 24A is connected between the anodes of the two first diodes 23 connected to the adjacent voltage dividing points 21P; however, the number of third diodes 24A may be 2 or more to apply appropriate voltages to the anodes of the first diodes 23.

For example, if the voltage applied to the anode of the first diode 23 connected to the voltage dividing point 21P with Identification No. #2 is excessively low, the second transistor 12 at the second stage turns off on occasions. To keep, at a desirable voltage, the voltage applied to the anode of the first diode 23 connected to the voltage dividing point 21P with Identification No. #2, the number of third diodes 24A connected between the anode of the first diode 23 connected to the voltage dividing point 21P with Identification No. #2 and the reference potential may be 2 or more.

For a smaller influence of the voltages at the voltage dividing points 21P divided by the resistor voltage divider circuit 21 over the voltages divided by the multi-stage diode circuit 24, the third diodes 24A having an ON resistance lower than the ON resistance of the first diodes 23 are desirably used.

Since the off state of the third diode 24A prevents an appropriate voltage division ratio, the total of the forward voltages of the plurality of third diodes 24A (the forward voltage of the multi-stage diode circuit 24) is desirably lower than the reference voltage Vgf₁. If the forward voltage of the multi-stage diode circuit 24 is excessively lower than the reference voltage Vgf₁, excessive forward current flows to the multi-stage diode circuit 24. To suppress the forward current flowing to the multi-stage diode circuit 24, the forward voltage of the multi-stage diode circuit 24 is desirably made close to the reference voltage Vgf₁. For example, the forward voltage of the multi-stage diode circuit 24 is lower than or equal to the reference voltage Vgf1; however, it is desirable to decide the number of third diodes 24A to minimize a difference between the forward voltage of the multi-stage diode circuit 24 and the reference voltage Vgf₁. For example, the number of third diodes 24A may desirably be decided such that increasing the number of third diodes 24A by one causes the forward voltage of the multi-stage diode circuit 24 to exceed the reference voltage Vgf₁ (for the maximum number of third diodes 24A for which the forward voltage of the multi-stage diode circuit 24 does not exceed the reference voltage Vgf1).

### Sixth Embodiment

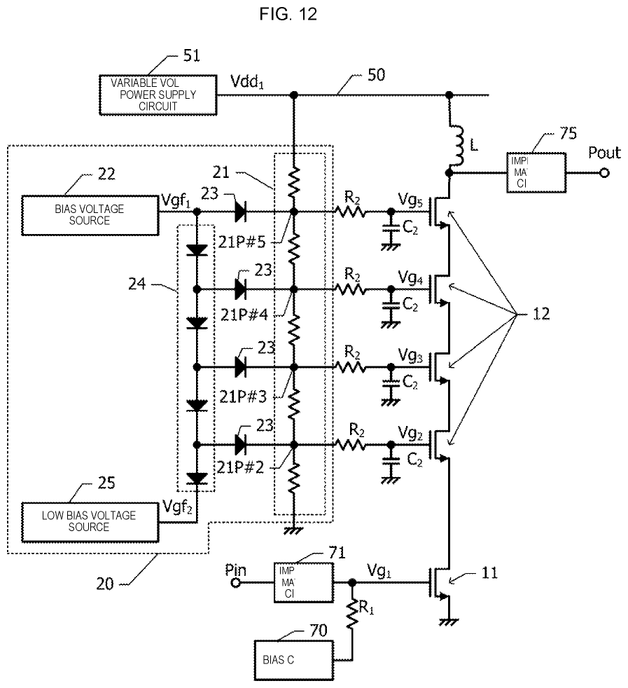

A cascode amplifier circuit according to Sixth Embodiment will then be described with reference to FIG. 12. The description of the configuration common to the cascode amplifier circuit according to Fifth Embodiment described with reference to FIG. 11 is hereinafter omitted.

FIG. 12 is an equivalent circuit diagram of the cascode amplifier circuit according to Sixth Embodiment. In Fifth Embodiment (FIG. 11), a lower voltage end portion of the multi-stage diode circuit 24 is connected to the reference potential. By contrast, in Sixth Embodiment, a lower voltage end portion of the multi-stage diode circuit 24 is connected to a low bias voltage source 25. The low bias voltage source 25 applies a low reference voltage Vgf₂ higher than the reference potential and lower than the reference voltage Vgf₁ to the end portion of the multi-stage diode circuit 24.

The effects of Sixth Embodiment will then be described.

In Sixth Embodiment, the low bias voltage source 25 is connected to the lower voltage end portion of the multi-stage diode circuit 24, and thus the low reference voltage Vgf₂ other than the reference potential may be applied. The degree of freedom in selecting one of the bias voltages Vg₂, Vg₃, Vg₄, and Vg₅ to be supplied to the plurality of second transistors 12 is thus enhanced. For example, assume a case where the bias voltage Vg₂ to the second transistor 12 at the second stage becomes excessively low in response to the application of the reference potential to the lower voltage end portion of the multi-stage diode circuit 24. In this case, the low reference voltage Vgf₂ is set higher than the reference potential, and thereby an issue that the bias voltage Vg₂ to the second transistor 12 at the second stage becomes excessively low may be avoided.

### Seventh Embodiment

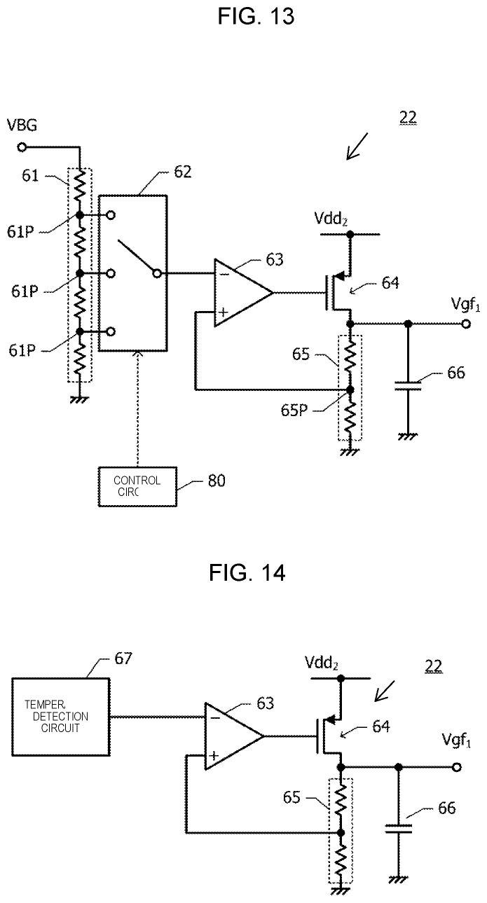

A cascode amplifier circuit according to Seventh Embodiment will then be described with reference to FIG. 13. The description of the configuration common to the cascode amplifier circuit according to First Embodiment described with reference to FIGS. 1 and 2 is hereinafter omitted.

FIG. 13 is an equivalent circuit diagram of a bias voltage source 22 of the cascode amplifier circuit according to Seventh Embodiment. In First Embodiment (FIG. 1), the reference voltage Vgf₁ generated by the bias voltage source 22 has a fixed value. By contrast, in Seventh Embodiment, the bias voltage source 22 can change the reference voltage Vgf₁.

A bandgap voltage VBG is applied to one end of a resistor voltage divider circuit 61 having a plurality of voltage dividing points 61P, and the reference potential is applied to the other end. A switch 62 is used to select one of the plurality of voltage dividing points 61P of the resistor voltage divider circuit 61 in accordance with a control signal inputted from a control circuit 80 and to connect the selected voltage dividing point 61P to the output node. A voltage at the voltage dividing point 61P selected with the switch 62 is inputted to the inverting input node of an operational amplifier 63.

A power supply voltage Vdd₂ is applied to an end portion, on the transistor side, of a series connection circuit including a transistor 64 formed from a PMOSFET and a resistor voltage divider circuit 65, and the reference potential is applied to an end portion on the resistor voltage divider circuit 65 side. More specifically, the source and the drain of the transistor 64 are respectively connected to the power supply voltage Vdd₂ and the resistor voltage divider circuit 65.

A voltage dividing point 65P of the resistor voltage divider circuit 65 is connected to the non-inverting input node of the operational amplifier 63. The output node of the operational amplifier 63 is connected to the gate of the transistor 64. The drain of the transistor 64 is connected to the reference potential via a capacitor 66. The reference voltage Vgf₁ is outputted from the drain of the transistor 64.

Control is performed to cause the voltage at the voltage dividing point 65P of the resistor voltage divider circuit 65 to match the voltage at one of the voltage dividing points 61P that is selected with the switch 62. As a result, the reference voltage Vgf₁ based on the voltage at the voltage dividing point 61P selected with the switch 62 and the voltage division ratio of the resistor voltage divider circuit 65 is outputted. The bias voltage source 22 is thus configured to change the reference voltage Vgf₁ in accordance with a control signal inputted from the control circuit 80.

The effects of Seventh Embodiment will then be described.

In Seventh Embodiment, the reference voltage Vgf₁ may be changed. For example, the control circuit 80 controls the switch 62 based on the operating range of the power supply voltage Vdd₁, the operating frequency band of the cascode amplifier circuit, a power mode (for example, a normal mode or a low-power mode) of the cascode amplifier circuit, and the like, and thereby control may be performed to have an appropriate lower-limit value of the bias voltages to the second transistors 12 (FIG. 1).

The function, according to Seventh Embodiment, of causing the bias voltage source 22 to change the reference voltage Vgf₁ may also be applicable to the cascode amplifier circuit according to any of Second Embodiment (FIG. 7), Third Embodiment (FIG. 8), Fourth Embodiment (FIG. 10), Fifth Embodiment (FIG. 11), and Sixth Embodiment (FIG. 12).

### Eighth Embodiment

A cascode amplifier circuit according to Eighth Embodiment will then be described with reference to FIG. 14. The description of the configuration common to the cascode amplifier circuit according to Seventh Embodiment described with reference to FIG. 13 is hereinafter omitted.

FIG. 14 is an equivalent circuit diagram of a bias voltage source 22 of the cascode amplifier circuit according to Eighth Embodiment. In Seventh Embodiment (FIG. 13), a voltage at the voltage dividing point 61P selected based on a control signal from the control circuit 80 is applied to the inverting input node of the operational amplifier 63. By contrast, in Eighth Embodiment, an output voltage from a temperature detection circuit 67 is applied to the inverting input node of the operational amplifier 63. The temperature detection circuit 67 changes the output voltage based on, for example, the ambient temperature.

The effects of Eighth Embodiment will then be described.

For example, in response to a change in the ambient temperature, the forward voltages Vf of the first diodes 23 (FIG. 1) are changed. If the reference voltage Vgf₁ does not change in response to the change in the forward voltage Vf, the lower-limit value of the voltages at the voltage dividing points 21P is changed. In Eighth Embodiment, when the forward voltages Vf of the first diodes 23 are changed due to the temperature change, the reference voltage Vgf₁ is changed to compensate for the change. The lower-limit value of the voltages at the voltage dividing points 21P may thereby be kept constant. For example, in response to an ambient temperature increase, the forward voltages Vf of the first diodes 23 are decreased. The reference voltage Vgf₁ may be decreased based on the decrease amount of the forward voltages Vf.

In addition, a gain change of the cascode amplifier circuit due to an ambient temperature change may be compensated for. For example, in response to an ambient temperature increase, the gain of the cascode amplifier circuit is decreased. Increasing the reference voltage Vgf₁ at the time of the ambient temperature increase enables the gain decrease to be compensated for. At this time, the reference voltage Vgf₁ may be changed in consideration for changes in the forward voltages Vf of the first diodes 23 due to the temperature change.

A cascode amplifier circuit according to a modification of Eighth Embodiment will then be described.

In Eighth Embodiment, the temperature detection circuit 67 changes the output voltage based on the ambient temperature. In the modification of Eighth Embodiment, a configuration in which the output voltage of the temperature detection circuit 67 is changed based on a temperature change in any of the first diodes 23 (FIG. 1) and a temperature change in the first diode 23 and any of the second transistors 12 may be used. For example, the temperature detection circuit 67 has a temperature sensor, and the temperature sensor may be formed on the semiconductor substrate where the first diodes 23, the first transistor 11, or the second transistors 12 are formed and may be disposed in an area close to these elements.

The function, according to Eighth Embodiment, of causing the bias voltage source 22 to change the reference voltage Vgf₁ based on the temperature is also applicable to the cascode amplifier circuit according to any of Second Embodiment (FIG. 7), Third Embodiment (FIG. 8), Fourth Embodiment (FIG. 10), Fifth Embodiment (FIG. 11), and Sixth Embodiment (FIG. 12).

The above-described embodiments are provided for an illustrative purpose, and it goes without saying that the configuration illustrated in different embodiments can be partially replaced or combined. The same operations and effects of the same configuration of the plurality of embodiments are not referred to in each embodiment one by one. Further, the present disclosure is not limited to the above-described embodiments. For example, it is obvious for those skilled in the art that various modifications, improvements, combinations, and the like can be made.

What is claimed is:

1. A cascode amplifier circuit comprising:
a cascode connection circuit comprising:
a first transistor to which a radio frequency signal is input;
at least one second transistor that is cascode-connected to the first transistor;
a bias circuit configured to supply a bias to the at least one second transistor; and
a power supply wiring line through which a variable power supply voltage is applied to the cascode connection circuit,
wherein the bias circuit comprises:
a resistor voltage divider circuit that is connected between the power supply wiring line and a reference potential, that has at least one voltage dividing point corresponding to the at least one second transistor, and that is configured to supply the bias to the corresponding second transistor based on a voltage at the at least one voltage dividing point;
a bias voltage source configured to generate a reference voltage that serves as a base for the bias supplied to the at least one second transistor; and
at least one first diode connected between an output node of the bias voltage source and the at least one voltage dividing point, the at least one first diode being connected in a direction serving as a forward direction from the output node of the bias voltage source to the at least one voltage dividing point.

2. The cascode amplifier circuit according to claim 1, further comprising:
a second diode that is connected between the power supply wiring line and the resistor voltage divider circuit in a direction serving as a forward direction from the power supply wiring line to the resistor voltage divider circuit.

3. The cascode amplifier circuit according to claim 1, wherein the at least one first diode comprises a diode-connected transistor.

4. The cascode amplifier circuit according to claim 1, wherein the bias voltage source is configured to change the reference voltage based on a control signal inputted to the bias voltage source.

5. The cascode amplifier circuit according to claim 4, further comprising:
a temperature detection circuit configured to detect temperature and to provide the control signal to the bias voltage source based on the detected temperature.

6. The cascode amplifier circuit according to claim 1,
wherein the at least one second transistor comprises a plurality of second transistors that are cascode-connected to each other,
wherein the at least one voltage dividing point comprises a plurality of voltage dividing points that are cascode-connected to each other and that correspond to the plurality of respective second transistors, and
wherein the at least one first diode comprises a plurality of first diodes each connected to a corresponding one of a subset of the plurality of voltage dividing points.

7. The cascode amplifier circuit according to claim 6, wherein the bias voltage source has a plurality of output nodes, and is configured to apply reference voltages having different levels to the plurality of respective first diodes, the reference voltages being included in the reference voltage.

8. The cascode amplifier circuit according to claim 6, further comprising:
a multi-stage diode circuit comprising a plurality of third diodes that are connected between the output node of the bias voltage source and a low reference voltage that is lower than the reference voltage, the plurality of third diodes being connected in a direction serving as a forward direction from the reference voltage to the low reference voltage,
wherein at least one first diode of the plurality of first diodes is connected to the bias voltage source via at least one third diode of the plurality of third diodes of the multi-stage diode circuit, and
wherein a first diode of the plurality of first diodes is connected to the bias voltage source via a third diode of the plurality of third diodes, the first diode being connected via the third diode to a voltage dividing point of the plurality of voltage dividing points that is closer to the reference potential,
wherein a number of the voltage dividing points is greater than a number of the plurality of third diodes,
wherein the plurality of first diodes comprises a different first diode that is connected, via a different third diode, to a different voltage dividing point of the plurality of voltage dividing points that is closer to the power supply wiring line.

9. The cascode amplifier circuit according to claim 8, further comprising:
a low bias voltage source configured to generate, as the low reference voltage, a voltage greater than the reference potential.
